(19) United States
(12) Patent Application Publication
(10) Pub. No.: US 2007/0163634 A1
(43) Pub. Date: Jul. 19, 2007

(54) Solar cell, manufacturing method and manufacturing management system thereof, and solar cell module

(75) Inventors: Yoshifumi Wada, Shiga (JP); Shinichi Miki, Shiga (JP); Nobuo Kitamura, Kyoto (JP); Teruo Ogino, Shiga (JP); Yuko Fukawa, Mie (JP)

Correspondence Address: HOGAN & HARTSON L.L.P., 1999 AVENUE OF THE STARS, SUITE 1400, LOS ANGELES, CA, 90067, US

(73) Assignee: KYOCERA CORPORATION

(21) Appl. No.: 11/486,437

(22) Filed: Jul. 12, 2006

Related U.S. Application Data
(60) Provisional application No. 60/699,646, filed on Jul. 14, 2005.

(51) Int. Cl. H01L 31/00

(52) U.S. Cl. 136/252

(57) ABSTRACT

A solar cell includes: a semiconductor substrate having a light receiving surface, an anti-light receiving surface, and a side surface; a front-side electrode formed on a side of the light receiving surface of the semiconductor substrate; and a rear-side electrode formed on a side of the anti-light receiving surface of the semiconductor substrate. An identification mark is provided to at least one of a portion on the side of the light receiving surface, a portion on the side of the anti-light receiving surface, and the side surface of the semiconductor substrate.

### BACKGROUND OF THE INVENTION

1. Field of the Invention

The present invention relates to a solar cell, a manufacturing method and a manufacturing management system thereof, and a solar cell module.

2. Description of the Background Art

Solar cell modules are clean energy sources whose applications and range of use have been rapidly expanding in recent years. Generally, a management number is marked on each of solar cell modules installed in various places, and information such as the date of manufacture, manufacturing method, output, and type of the solar cell module is managed by means of the management number (see Japanese Patent Application Laid-Open No. 11-261095 (1999), for example).

The management number and the like for identifying a solar cell module has been formed by various methods which include: affixing of a label to the surface of the solar cell module; filling of the solar cell module with a label, a tape and the like along with a solar cell using a filling material such as EVA or PVB; and marking on the filling material itself.

Meanwhile, recycling of solar cell modules has recently been under active study. This is an attempt to retrieve solar cell modules damaged or reduced in output characteristics due to a longtime harsh use environment and the like, and assemble them again as solar cell modules for reuse. When reusing solar cells during this recycling process, solar cells are taken out of a plurality of solar cell modules to be reused.

However, all of the aforementioned methods are directed to management in units of solar cell modules or solar cell arrays as a combination of a plurality of solar cell modules. Accordingly, an identification number as well as information such as the date and country of manufacture, and a manufacturer are unknown about a solar cell taken out of a solar cell module.

Further, in a solar cell module with the output characteristics thereof reduced due to a problem caused by a solar cell in use, the management in units of solar cell modules make it difficult to obtain information on the solar cell having caused the reduction in output characteristics.

There have been proposed a marking method through the use of an electrode material of a solar cell (see Japanese Utility Model Application Laid-Open No. 5-93054 (1993), for example), and a method of forming a collecting electrode of a solar cell as a specific letter, a symbol or a figure (see Japanese Patent Application Laid-Open No. 2002-064214, for example).

### SUMMARY OF THE INVENTION

In view of the above, the present invention has an object to provide a solar cell capable of being managed more strictly than has conventionally been managed by managing information on each of solar cells used in a solar cell module, a manufacturing method and a manufacturing management system of the solar cell, and a solar cell module.

In a first aspect of the present invention, a solar cell includes: a semiconductor substrate having a light receiving surface, an anti-light receiving surface, and a side surface; a front-side electrode formed on a side of the light receiving surface of the semiconductor substrate; and a rear-side electrode formed on a side of the anti-light receiving surface of the semiconductor substrate. An identification mark is provided to at least one of a portion on the side of the light receiving surface, a portion on the side of the anti-light receiving surface, and the side surface of the semiconductor substrate.

According to the first aspect, the identification mark is provided to at least one of a portion on the side of the light receiving surface, a portion on the side of the anti-light receiving surface, and the side surface of the semiconductor substrate. Accordingly, information on each of the solar cells used in the solar cell module can be managed, which is stricter management than has been conventionally done.

In a second aspect of the present invention, a method of manufacturing a solar cell includes the steps of: forming a front-side electrode on a side of a light receiving surface of a semiconductor substrate, the semiconductor substrate including the light receiving surface, an anti-light receiving surface, and a side surface; forming a rear-side electrode on a side of the anti-light receiving surface of the semiconductor substrate; and providing an identification mark to at least one of a portion on the side of the light receiving surface, a portion on the side of the anti-light receiving surface, and the side surface of the semiconductor substrate.

According to the second aspect, a step is included to provide the identification mark to at least one of a portion on the side of the light receiving surface, a portion on the side of the anti-light receiving surface, and the side surface of the semiconductor substrate. Accordingly, information on each of the solar cells used in the solar cell module can be managed, which is stricter management than has been conventionally done.

In a third aspect of the present invention, a solar cell module includes: a plurality of solar cells, the cells each including a light receiving surface, an anti-light receiving surface, and a side surface; and an inner lead connecting the plurality of solar cells. An identification mark is provided to at least one of a portion on a side of the light receiving surface, a portion on a side of the anti-light receiving surface, and the side surface of each of the solar cells, the identification mark being provided to all of the plurality of solar cells.

According to the third aspect, the identification mark is provided to at least one of a portion on the side of the light receiving surface, a portion on the side of the anti-light receiving surface, and the side surface of each of the solar cells forming the solar cell module, with the identification mark being provided to all of the plurality of solar cells. Accordingly, information on each of the solar cells used in the solar cell module can be managed.

In a fourth aspect of the present invention, a manufacturing management system of a solar cell, the solar cell being manufactured from a semiconductor substrate having been inserted into a plurality of manufacturing devices, processed, and taken out, includes: an identification mark acquisition unit obtaining an identification mark provided to the solar cell, the identification mark acquisition unit being provided to at least one of an inlet, an outlet and the inside of each of the manufacturing devices; and a server device bringing the identification mark into correspondence with inherent information on the solar cell for accumulation, the server device being connected to the identification mark acquisition unit.

According to the fourth aspect, each of the solar cells can be further strictly managed.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A to 1F illustrate a manufacturing method of a solar cell according to the present invention;

FIG. 2 illustrates a solar cell having an identification mark provided on a light receiving surface side thereof according to the present invention;

FIG. 3 illustrates solar cells each having an identification mark provided on a light receiving surface side thereof in a solar cell module according to the present invention;

FIG. 4 illustrates a solar cell having an identification mark provided on an anti-light receiving surface side thereof according to the present invention;

FIG. 5 illustrates solar cells each having an identification mark provided on an anti-light receiving surface side thereof in a solar cell module according to the present invention;

FIG. 6 illustrates a solar cell having an identification mark provided on a side surface thereof according to the present invention; and

FIG. 7 shows a block diagram of a manufacturing management system of a solar cell according to the present invention.

### DESCRIPTION OF THE PREFERRED EMBODIMENTS

The present invention is specifically described below based on the attached drawings.

<<Solar Cell and Manufacturing Method Thereof, and Solar Cell Module>>

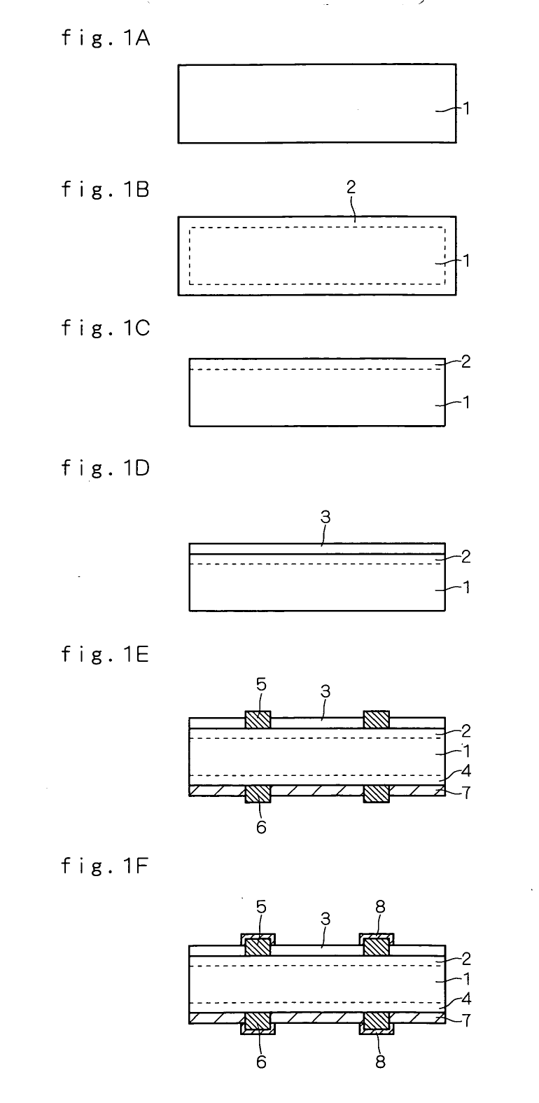

FIGS. 1A to 1F show cross-sectional views of a manufacturing method of a solar cell according to the present invention, with a bulk type silicon solar cell as an example. FIGS. 2, 4 and 6 show solar cells having an identification mark provided in portions thereof.

Namely, this solar cell basically includes a semiconductor substrate 1 having a light receiving surface, an anti-light receiving surface, and a side surface, a front-side electrode 5 formed on the light receiving surface side of the semiconductor substrate 1, and a rear-side electrode (output extract electrode 6 and a collecting electrode 7) formed on the anti-light receiving surface side of the semiconductor substrate 1, with identification marks 10A, 10B and 10C provided to at least one of a portion on the light receiving surface side, a portion on the anti-light receiving surface side, and the side surface of the semiconductor substrate 1.

A basic manufacturing method of the solar cell will be described first, and a specific structure of the identification marks 10A, 10B and 10C will be described thereafter.

<Basic Manufacturing Method of Solar Cell>

First, the semiconductor substrate 1 is prepared. The semiconductor substrate 1 is made of monocrystalline silicon, polycrystalline silicon or the like. The semiconductor substrate 1 (silicon substrate) contains semiconductor impurities of one conductive type, such as boron (B), on the order of 1×10¹⁶ to 1×10¹⁸ atoms/cm³, and has specific resistance on the order of 1.5 Ωcm. A pulling method or the like is used for monocrystalline silicone, and a casting method or the like for polycrystalline silicon. A polycrystalline silicone substrate can be mass-manufactured and is thus advantageous over a monocrystalline silicone substrate in terms of manufacturing cost. An ingot formed with the pulling method or the casting method is cut into the size on the order of 15 cm×15 cm, and then sliced to the thickness on the order of 300 to 500 μm, to give the semiconductor substrate 1.

Then, the surface is etched with an alkaline solution and the like to remove damage and contamination that adhered to the surface at the time of slicing or cutoff, to be cleaned. During or after the cleaning, the surface of the semiconductor substrate 1 is roughened by alkali etching or RIE (reactive ion etching) treatment.

Next, the semiconductor substrate 1 (silicon substrate) is placed in a diffusion furnace and heated in phosphorus oxychloride (POCl₃) and the like, to diffuse phosphorous atoms on the order of 1×10¹⁹ to 1×10²¹ atoms/cm³ on the surface portion of the semiconductor substrate 1 (silicon substrate), thereby forming a diffusion layer 2 exhibiting another conductivity type (see FIG. 1B). The diffusion layer 2 is formed to have a depth on the order of 0.2 to 0.5 μm and sheet resistance of not less than 40 Ω/□. Leaving only the diffusion layer 2 on one main surface side of the semiconductor substrate 1 (silicon substrate) unetched, the remaining diffusion layer 2 is etched (see FIG. 1C).

Next, an antireflection film 3 is formed on the one main surface side of the semiconductor substrate 1 (silicon substrate). The antireflection film 3 is formed from a silicon nitride film and the like, and formed by plasma CVD and the like using mixed gas of silane and ammonia. The antireflection film 3 is provided for preventing reflection of light on the surface of the semiconductor substrate 1 (silicon substrate) to effectively take light into the semiconductor substrate 1 (silicon substrate) (see FIG. 1D).

Subsequently, a portion of the antireflection film 3 that corresponds to the front-side electrode 5 is etched, applied with an electrode paste, and then baked to form the front-side electrode 5 (see FIG. 1E). The front-side electrode 5 may be formed by the so-called fire through method, in which the electrode paste is applied directly onto the antireflection film 3 and then baked so that the antireflection film 3 under the paste is melted and brought into direct contact with the semiconductor substrate 1 (silicon substrate). The electrode paste is also applied on the rear surface and then baked to form the output extract electrode 6. This electrode paste is baked such that glass flit is added to a silver powder and an organic vehicle in the proportion of 0.1 to 5 parts by weight of the glass flit to 100 parts by weight of silver to be made into a paste form, which is printed by a screen printing method and then baked at 600 to 800° C. for about one to 30 minutes.

In addition, the collecting electrode 7 is formed on the rear surface such that glass flit is added to an aluminum powder and an organic vehicle in the proportion of 0.1 to 5 parts by weight of the glass flit to 100 parts by weight of aluminum to be made into a paste form, which is printed by a screen printing method and then baked. Simultaneously with the formation of the collecting electrode 7, aluminum is diffused on the rear surface side of the semiconductor substrate 1 as a silicon substrate to form a BSF layer 4. The glass flit used herein is made of a material containing at least one of PbO, B₂O₃ and SiO₂, and having a softening point of not higher than 500° C. Thereafter, a solder layer 8 may be formed on the electrode surface to ensure long-term reliability and to connect solar cells 9 via an inner lead 11 later (see FIG. 1F).

During or before and after the respective steps described above, identification marks 10A to 10C including a number, a letter, a symbol and the like are formed on one of the light receiving surface side, the anti-light receiving surface side, and the side surface of each of the semiconductor substrates 1 by methods to be described later, or marking by laser, sandblast and the like, or the application of chemical-resistant ink and the like. The identification marks 10A to 10C are displayed by a difference in at least one of color, height and material of the surroundings of the identification marks 10A to 10C.

While the identification marks 10A to 10C may be formed in any portion on the light receiving surface side, the anti-light receiving surface side, or the side surface of the solar cell 9, they are preferably formed on the outer portion of the surface or the rear surface of the semiconductor substrate 1, or the side surface of the semiconductor substrate 1 so as to be visible when the solar cell 9 is completed. The identification marks 10A to 10C are further preferably formed on the outer portion of the rear surface or the side surface so as to prevent a reduction in output characteristics of the solar cell 9.

The identification marks 10A to 10C are formed through appropriate steps in accordance with their forming methods, as described later.

Each forming position of the identification marks 10A to 10C is described more specifically.

<Light Receiving Surface Side>

FIG. 2 illustrates a solar cell having an identification mark provided on a light receiving surface side thereof.

In FIG. 2, numeral 9 denotes a solar cell, numeral 5 denotes a front-side electrode, and numeral 10A denotes an identification mark.

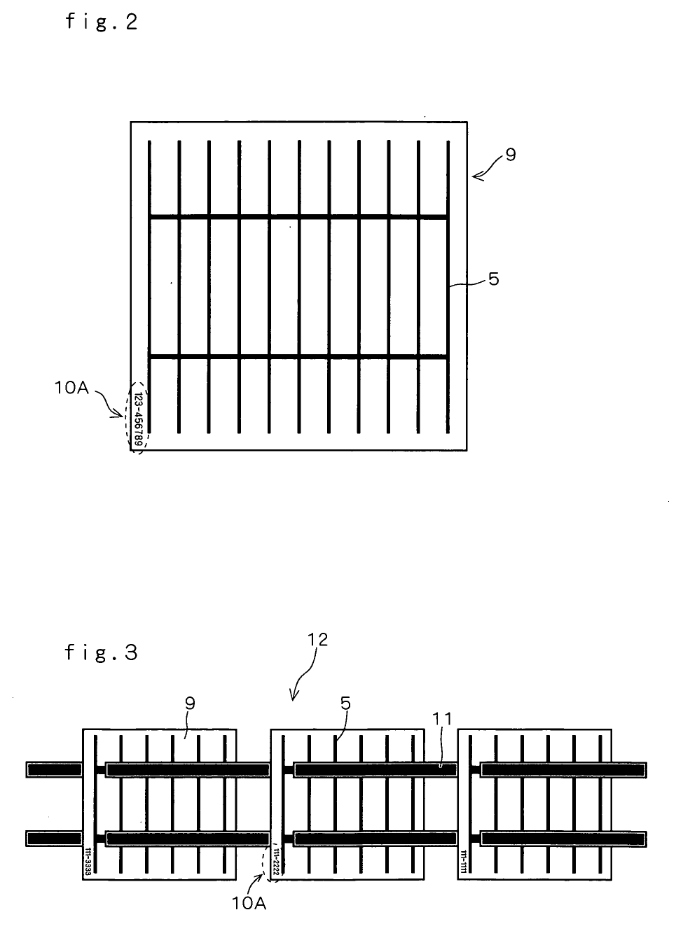

The identification mark 10A should not be provided in a position over the front-side electrode 5. If provided, the identification mark 10A will become invisible when the solar cells 9 are connected via the inner lead 11 later, as shown in FIG. 3. When the solder layer 8 is formed on the surfaces of the electrodes 5 and 6 of the solar cell 9, the identification mark 10A should not be provided over the solder layer 8, either. If provided, the identification mark 10A will become invisible when the solder melts at the time of connection to the inner lead 11.

FIG. 3 illustrates solar cells each having an identification mark provided on a light receiving surface side thereof in a solar cell module according to the present invention.

In FIG. 3, numeral 9 denotes a solar cell, numeral 5 denotes a front-side electrode, numeral 10A denotes an identification mark, numeral 11 denotes an inner lead, and numeral 12 denotes a solar cell module. As shown, the identification mark 10A is provided to each of the solar cells 9 used in the solar cell module 12. The identification mark 10A may be provided in any position. When the identification mark 10A is provided to a position visible from the light receiving surface side after connecting the inner lead 11 as shown in FIG. 3, the solar cell 9 can be identified from outside without having to disassemble the solar cell module 12. However, when the identification mark 10A is provided in a position shadowed by the inner lead 11 after connecting the inner lead 11, the light receiving area is not reduced.

<Anti-Light Receiving Surface Side>

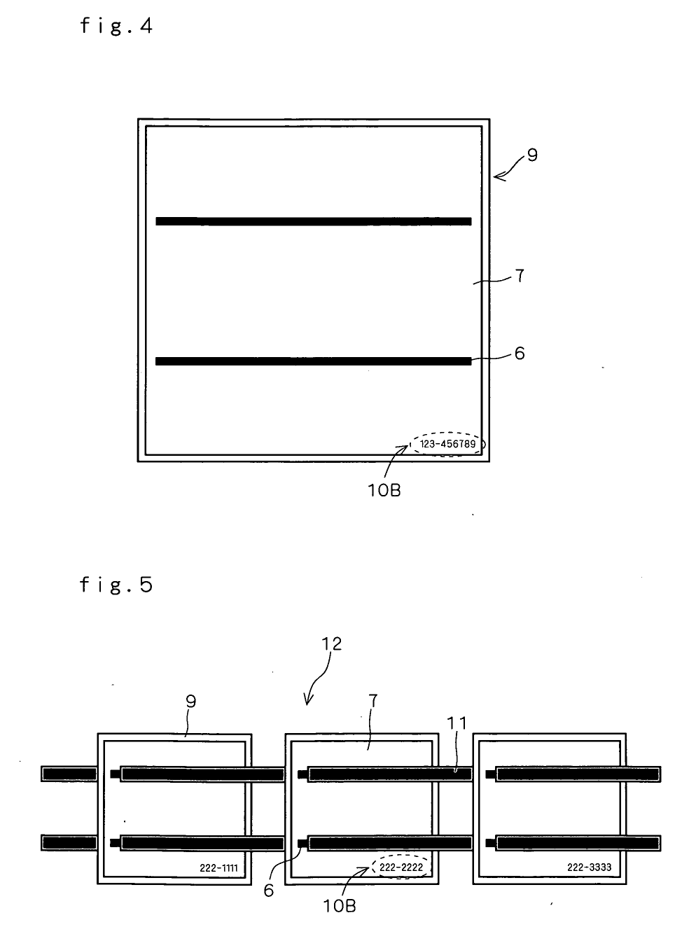

FIG. 4 illustrates a solar cell having an identification mark provided on an anti-light receiving surface side thereof.

In FIG. 4, numeral 9 denotes a solar cell, numeral 6 denotes an output extract electrode, numeral 7 denotes a collecting electrode, and numeral 10B denotes an identification mark. The output extract electrode 6 and the collecting electrode 7 are rear-side electrodes. The identification mark 10B should not be provided in a position over the output extract electrode 6. If provided, the identification mark 10B will become invisible when the solder layer 8 is formed on the surface of the output extract electrode 6 for connecting the solar cells 9 via the inner lead 11 later, as shown in FIG. 5. The identification mark 10B should not be provided in a position over the solder layer 8, either. If provided, the identification mark 10B will become invisible when the solder melts at the time of connection to the inner lead 11.

A method of providing the identification mark 10B to the anti-light receiving surface side is described by taking the case as an example where the output extract electrode 6 is formed by baking a paste containing silver as the main component and the collecting electrode 7 is formed by baking a paste containing aluminum as the main component. When the collecting electrode 7 is formed on the rear surface of the solar cell 9 as shown in FIG. 1E, an electrode material containing aluminum as the main component is applied on the collecting electrode 7 except a portion where the identification mark 10B is to be provided, to thereby display the identification mark 10B. Consequently, the identification mark 10B is rendered different in at least one of color, height and material from the collecting electrode 7 surrounding the identification mark 10B, to be identified.

Alternatively, the identification mark 10B may be formed in the same step and with the same material as the output extract electrode 6 simultaneously with the formation of the output extract electrode 6. In this case, it is preferable that the identification mark 10B and the output extract electrode 6 be formed separately, so that the identification mark 10B is easily seen and the area of the output extract electrode 6 is kept constant.

Such formation of the identification mark 10B simultaneously with the formation of the output extract electrode 6 or the collecting electrode 7 as the rear-side electrode allows the identification mark 10B to be formed without increasing the number of steps.

It is to be noted that the scope of the present invention is not restricted by the above-described method of displaying the identification mark 10B on the anti-light receiving surface side of the solar cell 9. The identification mark 10B may be provided to any position except for a position over the output extract electrode 6. As described above, the identification mark 10B may be formed over the collecting electrode 7 as a rear-side electrode after forming the collecting electrode 7, or in some other portion. Or when the solar cell 9 has another rear-side electrode structure that does not include the collecting electrode 7 made of aluminum, the identification mark 10B may be formed in a portion other than a portion upon which the solder layer 8 is to be formed.

FIG. 5 illustrates solar cells each having an identification mark provided on an anti-light receiving surface side thereof in a solar cell module according to the present invention.

In FIG. 5, numeral 9 denotes a solar cell, numeral 6 denotes an output extract electrode, numeral 7 denotes a collecting electrode, numeral 10B denotes an identification mark, numeral 11 denotes an inner lead, and numeral 12 denotes a solar cell module. As shown, the identification mark 10B is provided to each of the solar cells 9 used in the solar cell module 12. The identification mark 10B may be provided in any position. The anti-light receiving surface side is suitable for being provided with the identification mark 10B due to the nonoccurrence of the light receiving area reduction problem, which occurs on the light receiving surface side. The solar cell module 12 typically has a structure in which the solar cell 9 is interposed between a transparent substrate and a rear surface protective sheet. A rear surface protective sheet, which is typically thinner and softer than a transparent substrate, is usually easier to peel than a transparent substrate. This facilitates identification of the solar cell 9. Even a solar cell module having a transparent substrate also for the rear surface thereof has been mass-manufactured recently. In such case, the solar cell 9 even on the anti-light receiving surface side can be identified without having to disassemble the solar cell module 12.

<Side Surface>

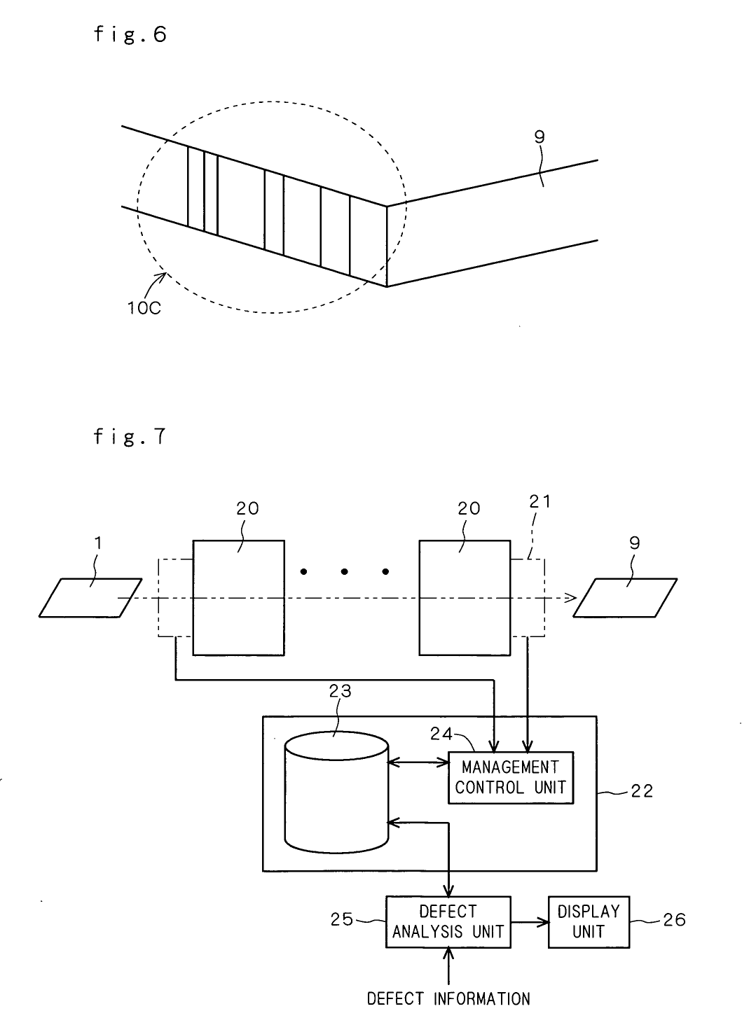

FIG. 6 illustrates a solar cell having an identification mark provided on a side surface thereof.

In FIG. 6, numeral 9 denotes a solar cell, and numeral 10C denotes an identification mark.

The identification mark 10C may be provided in any position. It is difficult, however, to mark a number or a character on the side surface of the bulk type silicon solar cell 9 which has a relatively large thickness but usually uses a silicon substrate on the order of 300 μm. It is therefore desirable to form the identification mark 10C in the form of barcode and the like. Line marking methods such as bar coding include dicing, laser, blasting, hydraulic pressure and the like. In any of the methods, it is preferable not to vertically irradiate the side surface of the solar cell 9, but to press the solar cell 9 from the side surface to irradiated light for example in a direction from the light receiving surface side to the anti-light receiving surface side of the solar cell 9, or the anti-light receiving surface side to the light receiving surface side of the solar cell 9. This prevents the other portion of the solar cell 9 from being damaged when the identification mark 10C is formed. Consequently, the identification mark 10C is rendered different in color or height from the surroundings, to be identified.

In addition, a plurality of the solar cells 9 each having the identification mark 10C provided on the side surface thereof may be connected via an inner lead to form a solar cell module. The solar cell module thus formed, when used as the solar cell module 12 having transparent substrates for both of the surface and rear surface thereof like the so-called light through module, does not spoil the design because the identification marks 10C are invisible from the appearance of the solar cell module 12.

It is to be noted that the scope of the present invention is not restricted by the above-described method of displaying the identification mark 10C on the side surface of the solar cell 9. For example, the identification mark 10C may be provided by physical damage as described above, or by chemical damage such as etching, or by applying a resist or a paste to the side surface, and baking them.

The solar cell 9 is formed through such steps as described above. By managing information on each of the solar cells 9, stricter management than has been conventionally done can be performed while suppressing the occurrence of a reduction in electric characteristics.

It is particularly to be noted that the formation of the identification marks 10A to 10C at the initial stage of manufacturing the solar cell 9 allows management of information on the solar cell 9 in the long manufacturing process. Accordingly, at the occurrence of a problem with the output characteristics or long-term reliability of the solar cell 9, a step having caused the problem can be identified very easily.

Further, even when the surface of the solar cell 9 is roughened by the RIE method, unevenness-forming-etching and the like to reduce reflectivity, or when the rear surface of the solar cell 9 is almost entirely covered with an electrode such as aluminum, the above-described structures and methods of providing the identification marks 10A to 10C make it possible to read a pattern on the surface of the solar cell 9 after the reflectivity reduction process or the rear-side electrode formation. Namely, the identification marks 10A to 10C can be read through the manufacturing steps until the completion of the solar cell 9. Accordingly, by reading the identification marks 10A to 10C in each manufacturing step and bringing them into correspondence with manufacturing data (inherent information), for example, individual management can be performed while maintaining data integrity.

In a conventional structure where an electrode is formed as a specific character, a symbol or a figure, the symbol for identifying a solar cell needs to be different in each of solar cells or in units of a plurality of kinds of solar cells. This causes a difference in electrode shape among each of solar cells or in units of a plurality of kinds of solar cells, resulting in a difference in light receiving area or collecting efficiency. Meanwhile, in the semiconductor substrate 1 having the identification marks 10B and 10C provided to the anti-light receiving surface side or the side surface thereof, an influence upon the light receiving area is prevented, thereby giving stability to the electric characteristics.

Moreover, with the provision of the identification marks 10A to 10C to all of the plurality of the solar cells 9 as described above, the information on each of the solar cells 9 used in the solar cell module can be managed. As for the solar cell 9 having the identification mark 10A provided to the light receiving surface side thereof, the identification mark 10A can be identified without having to disassemble the solar cell module. As for the solar cells 9 having the identification marks 10B and 10C provided to the anti-light receiving surface side or the side surface thereof, the light receiving area is not reduced, thus preventing a reduction in output characteristics of the solar cell module 12. The solar cell module thus formed, when used as the solar cell module 12 having transparent substrates for both of the surface and rear surface thereof like the so-called light through module, does not spoil the design because the identification marks 10C are invisible from the appearance of the solar cell module 12.

<<Manufacturing Management System of Solar Cell>>

A manufacturing management system of the solar cell 9 is described. FIG. 7 shows a block diagram of the manufacturing management system.

The semiconductor substrate 1 is first inserted into a plurality of manufacturing devices 20 (RIE device, diffusion device, CVD device, baking device) to be subjected to a predetermined process, and taken out as the solar cell 9. During or before and after the respective steps during the process, the identification marks 10A to 10C including a number, a letter, a symbol and the like are formed on each of the semiconductor substrates 1 of the solar cell 9 with the above-described methods, or marking by laser and the like, or the application of chemical-resistant ink and the like.

At this time, the identification marks 10A to 10C provided to the solar cell 9 are obtained by an identification mark acquisition unit 21. The identification mark acquisition unit 21 is at least one reader disposed at the inlet or outlet of any one of the manufacturing devices 20, to read and obtain the identification marks 10A to 10C provided.

The identification mark acquisition unit 21 is connected to a server device 22. The server device 22 includes a management control unit 24, and a storage device 23 having a hard disk device and the like. The inherent information on each of the semiconductor substrates 1 is brought into correspondence with the identification marks 10A to 10C, to be registered and accumulated in the server device 22. The inherent information in the stage of the semiconductor substrate 1 includes a silicon raw material, the device number of a manufacturing device for the semiconductor substrate 1, the date of manufacture, the device numbers of a cutting device and a slicing device, and the position of the semiconductor substrate 1 in the ingot. The inherent information possessed by one of the solar cells 9 in the subsequent steps concerns the various processing devices (e.g., RIE device, diffusion device, CVD device, baking device), the date and time of treatment of the devices, the arrangement position of the semiconductor substrate 1 in the devices, an electrode material lot, a processing liquid lot, and a working gas lot.

Then, the inherent information including information as to when and through what position of which device the semiconductor substrate 1 has passed is brought into correspondence with the identification marks 10A to 10C obtained by the identification mark acquisition unit 21, to be supplied to the server device 22. The server device 22 accumulates those pieces of information in the storage device 23. In addition, information such as the lot information on electrode material, processing liquid, working gas and the like, and maintenance, parts exchange, setting change and the like of the various devices is also registered with the server device 22, to accumulate all the inherent information on each of the solar cells 9 in the server device 22.

Namely, assuming that the semiconductor substrate 1 provided with an identification number A is made of a material B, and passed through a substrate manufacturing device C, a cutting device D, a slicing device C1, a processing device E, a diffusion device F, a CVD device G, an RIE device H, and a baking furnace I at a specific date (year/month/day) and time (hour/minute/second), to be completed, using a processing liquid J, an electrode material K and a gas L, information that includes all the above items is stored into the server device 22.

Such management helps, when one of the solar cells 9 completed has low output characteristics, tracking down a device, a material or the like that has caused the problem by combining the data of those cells so the problem can be immediately dealt with. When an instantaneous blackout occurs due to lightening or the like, followed by a temporary reduction in temperature of the baking furnace, for example, the one of the solar cells 9 which was passing through the baking furnace at that moment can be identified and sorted out.

Further, the solar cell 9 having been modularized and used for a long period of time as a solar cell system can be recycled and reused with high reliability due to its clear history.

After completed, the solar cell 9 is typically irradiated with pseudo-sunlight to measure its output characteristics, or the strength of electrodes and the strength of the solar cell 9 itself. When the solar cells 9 having some inherent information agreeing with one another and have been found to be defective meet a predetermined number, or the measured items show values under a predetermined limit value, a warning function may be added to the server device 22 that notifies the operator of abnormality by displaying the inherent information that agreed to one another. This stabilizes the characteristics of the solar cell 9 quickly.

Namely, identification information on the solar cell 9 that has found to be defective is input to a defect analysis unit 25 connected to the server device 22. Such defect may come from actual use or from examination. The defect analysis unit 25 then accesses the storage device 23, to analyze an occurrence tendency of the defect. More specifically, when the number of inherent information on the solar cells 9 that have been found to be defective reaches a predetermined threshold value, the defect analysis unit 25 displays the inherent information through a display unit 26. For example, when the number of defective solar cells 9 made of a specific material B reaches a predetermined number, the defect analysis unit 25 displays a large number of defect occurrences with respect to the material B.

In such ways, with the provision of the identification marks 10A to 10C to each of the solar cells 9 and the management of individual data such as manufacturing process, raw material and output characteristics on the solar cells 9, stricter management than the conventional management in units of the solar cell module 12 can be performed, thereby greatly reducing the time and effort for recycling and reuse.

Although the identification mark acquisition unit 21 such as a reader is preferably installed on each of the devices 20, it may be installed only on a specific device that includes an instable element to have an effect on the characteristics of the solar cell 9. The identification mark acquisition unit 21 may be installed not only at the inlet or outlet of a device, but may be installed in a device capable of reading the identification marks 10A to 10C during a process.

<Modification>

It will be appreciated that the solar cell, the manufacturing method of the solar cell, and the manufacturing management system of the solar cell module and the solar cell according to the present invention are not restricted to the embodiments described above. It is therefore understood that numerous modifications and variations can be devised without departing from the scope of the invention.

For example, while the semiconductor device 1 is provided with the identification marks 10A to 10C upon completion thereof, the identification marks 10A to 10C may be formed after subjecting the semiconductor substrate 1 to some predetermined steps as described below, or may be formed with a predetermined material formed on the semiconductor substrate 1.

<Modification 1>

A method is described below of providing the identification mark 10A over an antireflection film 3 that is a silicon nitride film formed by plasma CVD.

Prior to forming the antireflection film 3 shown in FIG. 1D, a phosphorous paste is transferred onto the light receiving surface side with a numbering machine that automatically sends a number with each transfer, for example. By using the numbering machine, different numbers are consecutively transferred to the solar cells 9. The antireflection film 3 made of silicon nitride is formed thereon by plasma CVD, so that only a portion of the identification mark 10A is displayed with a different color from the other portion. This is attributed to formation of a reactant of the silicon nitride film and the phosphorous paste applied thereunder. The phosphorous paste may alternatively be a material (film-property altering paste) capable of altering such properties as the thickness and a refractive index of the later-formed silicon nitride film. When thermal treatment is to be added later, a material should be avoided that has an adverse effect on the output characteristics of the solar cell 9 by diffusing within the silicon substrate to break junctions. From this point of view, it is most appropriate to employ a paste made of phosphorous used for the formation of the diffusion layer 2.

As another method of providing the identification mark 10A over the antireflection film 3, it is effective to form the antireflection film 3 as shown in FIG. ID, and then apply a material (film-property altering paste) that alters the properties of the silicon nitride film, such as a phosphorous paste, on the antireflection film 3 with a numbering machine. Consequently, a reactant of the silicon nitride film and phosphorous is formed later, which allows only a portion of the identification mark 10A to be displayed with a different color from the other portion. Again, the phosphorous paste may alternatively be a material capable of altering the properties of the silicon nitride film.

In this manner, the antireflection film 3 is formed on the light receiving surface side of the solar cell 9, and the properties of the antireflection film 3 are partially altered to thereby form the identification mark 10A. This results in no reduction in light irradiation area, thus suppressing a reduction in characteristics of the solar cell 9. Another advantage is that the identification mark 10A of the solar cell 9 can be identified from the appearance of a solar cell module without having to disassemble the solar cell module.

<Modification 2>

The identification mark 10A may be formed in the same step and with the same material as the front-side electrode 5 simultaneously with the formation of the front-side electrode 5 shown in FIG. 1E. Consequently, the identification mark 10A is rendered different in color, height and material from the antireflection film 3, to be identified. In this case, it is preferable that the identification mark 10A and the front-side electrode 5 be formed separately, so that the identification mark 10A is easily seen and the area of the front-side electrode 5 is kept constant. This allows the front-side electrode 5 to maintain constant collecting efficiency regardless of the number of letters, or the length and shape of the symbols of the identification mark 10A.

In this manner, the identification mark 10A can be formed simultaneously with the formation of the front-side electrode 5 without increasing the number of steps.

<Modification 3>

It is also effective to provide the identification mark 10A with a solder resist. Such solder resist is applied on the light receiving surface side of the semiconductor substrate 1 prior to forming the solder layer 8. Consequently, the identification mark 10A is rendered different in height from the antireflection film 3 surrounding the identification mark 10A, to be identified. It is further preferable that the solder resist be transparent.

In this manner, the identification mark 10A can be displayed on the light receiving surface side without increasing the number of steps or reducing the light receiving area of the solar cell 9.

<Modification 4>

For a bulk type silicon solar cell, a silicon oxide film, a titanium oxide film, a magnesium oxide film and the like are used as the antireflection film 3. When those films are used as the antireflection film 3, the identification mark 10A may be made of a material that forms a reactant with those films. When the antireflection film 3 is not formed, the identification mark 10A may be formed separately from the front-side electrode 5.

<Modification 5>

As yet another method, the identification mark 10B may be provided by applying an aluminum paste on the portion of the collecting electrode 7 and then using a silver paste, for example. By performing baking thereafter, the identification mark 10B is rendered different in color and material from the collecting electrode 7 surrounding the identification mark 10B, to be identified.

<Modification 6>

Still alternatively, the identification mark 10B may be provided by marking after applying and baking an aluminum paste on the portion of the collecting electrode 7. Marking methods at high temperature include the use of laser, a branding iron and the like. With such method, the identification mark 10B can be displayed after the solar cell 9 is completed as shown in FIG. 1F and output measurements are performed. This allows the output characteristics or a classification by the output characteristics to be marked as well.

Consequently, the identification mark 10B is rendered different in color from the collecting electrode 7 surrounding the identification mark 10B, to be identified.

While the invention has been shown and described in detail, the foregoing description is in all aspects illustrative and not restrictive. It is therefore understood that numerous modifications and variations can be devised without departing from the scope of the invention.

What is claimed is:

1. A solar cell comprising:
a semiconductor substrate including a light receiving surface, an anti-light receiving surface, and a side surface;
a front-side electrode formed on a side of said light receiving surface of said semiconductor substrate; and
a rear-side electrode formed on a side of said anti-light receiving surface of said semiconductor substrate, wherein
an identification mark is provided to at least one of a portion on said side of said light receiving surface, a portion on said side of said anti-light receiving surface, and said side surface of said semiconductor substrate.

2. The solar cell according to claim 1, wherein
said identification mark includes at least one of a number, a letter, and a symbol.

3. The solar cell according to claim 1, wherein
said identification mark is displayed by a difference in at least one of color, height and material from the surroundings.

4. The solar cell according to claim 1, wherein
an antireflection film is formed on said side of said light receiving surface of said semiconductor substrate, and
said identification mark is formed in said antireflection film.

5. The solar cell according to claim 1, wherein
said rear-side electrode includes an electrode made of a material containing silver as main component, and
said identification mark is made of said material containing silver as main component on said side of said anti-light receiving surface of said semiconductor substrate, and provided in a portion other than a portion of said rear-side electrode made of said material containing silver as main component.

6. The solar cell according to claim 1, wherein
said identification mark is displayed in the form of lines on said side surface of said semiconductor substrate.

7. The solar cell according to claim 1, further comprising
an antireflection film formed on said side of said light-receiving surface of said semiconductor substrate, wherein
said identification mark is formed by partially altering a thickness of said antireflection film.

8. The solar cell according to claim 1, further comprising
an antireflection film formed on said side of said light-receiving surface of said semiconductor substrate, wherein
said identification mark is formed by partially altering a film property of said antireflection film.

9. The solar cell according to claim 1, wherein
said identification mark is formed by applying a solder resist on said side of said light-receiving surface of said semiconductor substrate.

10. The solar cell according to claim 1, wherein
said identification mark is formed by partially damaging said side surface of said semiconductor substrate.

11. A method of manufacturing a solar cell, comprising the steps of:
forming a front-side electrode on a side of a light receiving surface of a semiconductor substrate, said semiconductor substrate including said light receiving surface, an anti-light receiving surface, and a side surface;
forming a rear-side electrode on a side of said anti-light receiving surface of said semiconductor substrate; and
providing an identification mark to at least one of a portion on said side of said light receiving surface, a portion on said side of said anti-light receiving surface, and said side surface of said semiconductor substrate.

12. The method of manufacturing a solar cell according to claim 11, further comprising the steps of:
transferring a film-property altering paste in accordance with said identification mark onto said light receiving surface of said semiconductor substrate; and
forming an antireflection film on said side of said light receiving surface of said semiconductor substrate after transferring said film-property altering paste, to partially alter a film property of said antireflection film.

13. The method of manufacturing a solar cell according to claim 11, further comprising the steps of:
forming an antireflection film on said side of said light receiving surface of said semiconductor substrate; and
transferring a film-property altering paste in accordance with said identification mark onto said antireflection film to partially alter a film property of said antireflection film.

14. The method of manufacturing a solar cell according to claim 11, simultaneously executing the steps of:
forming either one of said front-side electrode and said rear-side electrode by applying and baking an electrode material including at least silver as main component on either one of said side of said light-receiving surface and said side of said anti-light receiving surface of said semiconductor substrate; and
forming said identification mark.

15. The method of manufacturing a solar cell according to claim 11, further comprising the steps of:
forming said rear-side electrode by applying and baking an electrode material including aluminum as main component on said side of said anti-light receiving surface of said semiconductor substrate; and
after forming said rear-side electrode with said electrode material including aluminum as main component, forming said identification mark over said rear-side electrode.

16. A solar cell module comprising:
a plurality of solar cells, said cells each including a light receiving surface, an anti-light receiving surface, and a side surface; and
an inner lead connecting said plurality of solar cells, wherein
an identification mark is provided to at least one of a portion on a side of said light receiving surface, a portion on a side of said anti-light receiving surface, and said side surface of each of said solar cells, said identification mark being provided to all of said plurality of solar cells.

17. A manufacturing management system of a solar cell, said solar cell being manufactured from a semiconductor substrate having been inserted into a plurality of manufacturing devices, processed, and taken out, said system comprising:
an identification mark acquisition unit obtaining an identification mark provided to said solar cell, said identification mark acquisition unit being provided to at least one of an inlet, an outlet and the inside of each of said manufacturing devices; and
a server device bringing said identification mark into correspondence with inherent information on said solar cell for accumulation, said server device being connected to said identification mark acquisition unit.

18. The manufacturing management system of a solar cell according to claim 17, further comprising:
a defect analysis unit analyzing, upon receipt of information on said identification mark of a solar cell having been found to be defective, an occurrence tendency of the defect based on said received information on said identification mark and information accumulated in said server device.

19. The manufacturing management system of a solar cell according to claim 18, wherein
when the number of inherent information on solar cells having been found to be defective reaches a predetermined threshold value, said defect analysis unit displays said inherent information.

20. The manufacturing management system of a solar cell according to claim 17, wherein
said inherent information includes information on at least one of the date of manufacture, the time of manufacture, the number of a manufacturing device, an arrangement position in said manufacturing devices, and a material.
